(19) United States
(12) Patent Application Publication
(10) Pub. No.: US 2020/0126818 A1
(43) Pub. Date: Apr. 23, 2020

(54) SUBSTRATE PROCESSING APPARATUS, SUBSTRATE PROCESSING METHOD, AND STORAGE MEDIUM

(71) Applicant: TOKYO ELECTRON LIMITED, Tokyo (JP)

(72) Inventors: Yosuke KAWABUCHI, Koshi City (JP); Kyoko IKEDA, Nirasaki City (JP)

(21) Appl. No.: 16/658,651

(22) Filed: Oct. 21, 2019

(30) Foreign Application Priority Data
Oct. 23, 2018 (JP) 2018-199486
Aug. 6, 2019 (JP) 2019-144427

(51) Int. Cl. H01L 21/67

(52) U.S. Cl. CPC H01L 21/6715; H01L 21/67248

(57) ABSTRACT

There is provided a substrate processing apparatus which includes a substrate holding part configured to hold a substrate; a drying liquid supply part configured to supply a drying liquid toward a front surface of the substrate held by the substrate holding part; a temperature adjustment part configured to change a temperature of the front surface of the substrate; and a controller configured to control the temperature adjustment part, wherein the controller controls the temperature adjustment part to generate a temperature difference in a liquid film of the drying liquid supplied onto the front surface of the substrate.

### CROSS-REFERENCE TO RELATED APPLICATIONS

This application is based upon and claims the benefit of priority from Japanese Patent Application Nos. 2018-199486 and 2019-144427, filed on Oct. 23, 2018, and Aug. 6, 2019, respectively, the entire contents of which are incorporated herein by reference.

### TECHNICAL FIELD

The present disclosure relates to a substrate processing apparatus, a substrate processing method, and a non-transitory computer-readable storage medium

### BACKGROUND

As a method of drying a substrate after a cleaning process, a method of supplying a drying liquid onto a front surface of the substrate, replacing a rinsing liquid or the like with the drying liquid, and removing the drying liquid has been studied (see Patent Document 1).

### PRIOR ART DOCUMENT

### Patent Documents

Patent Document 1: Japanese laid-open publication No. 2014-90015

### SUMMARY

According to one embodiment of the present disclosure, there is provided a substrate processing apparatus including: a substrate holding part configured to hold a substrate; a drying liquid supply part configured to supply a drying liquid toward a front surface of the substrate held by the substrate holding part; a temperature adjustment part configured to change a temperature of the front surface of the substrate; and a controller configured to control the temperature adjustment part, wherein the controller controls the temperature adjustment part to generate a temperature difference in a liquid film of the drying liquid supplied onto the front surface of the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view schematically showing a substrate processing system according to an illustrative embodiment.

FIG. 2 is a schematic view of a substrate processing apparatus according to an illustrative embodiment.

FIG. 3 is a flowchart for explaining a substrate processing method according to an illustrative embodiment.

FIGS. 4A to 4C are views for explaining an IPA discharging process by a temperature adjustment part according to a first embodiment.

FIGS. 5A to 5C are views for explaining an IPA discharging process by a temperature adjustment part according to a modification of the first embodiment.

FIGS. 6A to 6C are views for explaining an IPA discharging process by a temperature adjustment part according to a modification of the first embodiment.

FIGS. 7A to 7C are views for explaining an IPA discharging process by a temperature adjustment part according to a modification of a second embodiment.

FIGS. 8A to 8C are views for explaining an IPA discharging process by a temperature adjustment part according to a modification of the second embodiment.

FIGS. 9A to 9C are views for explaining an IPA discharging process by a temperature adjustment part according to a modification of the second embodiment.

FIGS. 10A to 10C are views for explaining an IPA discharging process by a temperature adjustment part according to a modification of the second embodiment.

FIGS. 11A and 11B are views for explaining another example of the IPA discharging process by the temperature adjustment part.

FIGS. 12A and 12B are views for explaining another example of the IPA discharging process by the temperature adjustment part.

FIG. 13 is a view for explaining another example of the IPA discharging process by the temperature adjustment part.

### DETAILED DESCRIPTION

Reference will now be made in detail to various embodiments, examples of c are illustrated in the accompanying drawings. Throughout the drawings, the same or equivalent parts will be denoted by the same reference numerals. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

### [Configuration of Substrate Processing System]

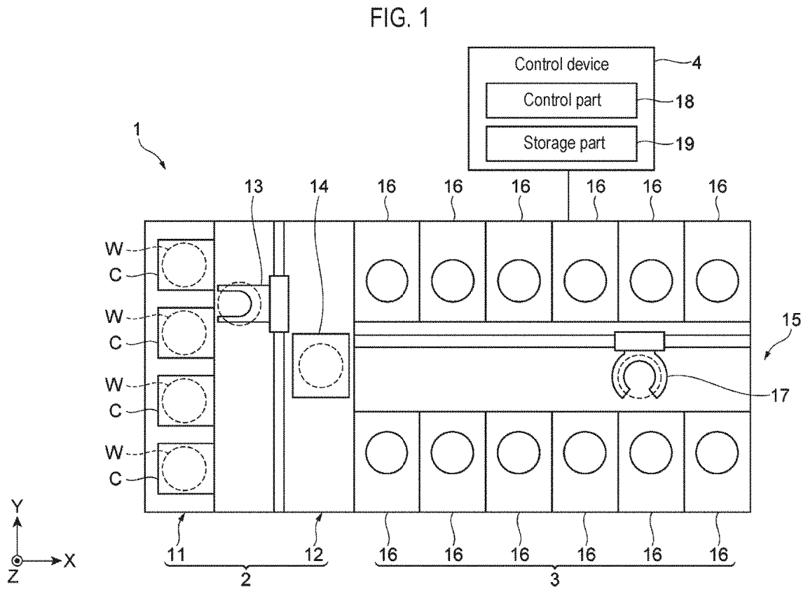

FIG. 1 is a view showing a schematic configuration of a substrate processing system according to a first embodiment. For clarification of a positional relationship, an X-axis direction, a Y-axis direction and a Z-axis direction, which are orthogonal to one another, are defined in the following description and a positive Z-axis direction is defined as a vertical upward direction.

As shown in FIG. 1, a substrate processing system 1 includes a loading/unloading station 2 and a processing station 3. The loading/unloading station 2 and the processing station 3 are provided adjacent to each other.

The loading/unloading station 2 includes a carrier stage 11 and a transfer part 12. A plurality of carriers C that accommodate a plurality of substrates, in this embodiment, semiconductor wafers (hereinafter referred to as wafers W) in a horizontal posture, are placed on the carrier stage 11.

The transfer part 12 is provided adjacent to the carrier stage 11 and includes a substrate transfer device 13 and a delivery part 14 provided therein. The substrate transfer device 13 includes a wafer holding mechanism that holds the wafer W. The substrate transfer device 13 is movable in the horizontal direction and the vertical direction and swingable around a vertical axis, and transfers the wafer W between the carrier C and the delivery part 14 using the wafer holding mechanism.

The processing station 3 is provided adjacent to the transfer part 12. The processing station 3 includes a transfer part 15 and a plurality of processing units 16. The plurality of processing units 16 are provided side by side on both sides of the transfer part 15.

The transfer part 15 includes a substrate transfer device 17 provided therein. The substrate transfer device 17 includes a wafer holding mechanism that holds the wafer W. The substrate transfer device 17 is movable in the horizontal direction and the vertical direction and swingable around a vertical axis, and transfers the wafer W between the delivery part 14 and each processing unit 16 using the wafer holding mechanism.

Each of the processing units 16 performs a predetermined substrate processing on the wafer W transferred by the substrate transfer device 17 wider the control of a controller 18 of a control part 4 to be described later.

The substrate processing system 1 further includes the control part 4. The control part 4 is, for example, a computer, and includes the controller 18 and a storage part 19. The storage part 19 stores a program for controlling various processes to be executed in the substrate processing system 1. The controller 18 controls the operation of the substrate processing system 1 by reading and executing the program stored in the storage part 19.

The program may be recorded in a non-transitory computer-readable storage medium and installed from the storage medium on the storage part 19 of the control part 4. Examples of the computer-readable storage medium may include a hard disk (HD), a flexible disk (FD), a compact disk (CD), a magnetic optical disk (MO), a memory card and the like.

In the substrate processing system 1 configured as above, first, the substrate transfer device 13 of the loading/unloading station 2 takes out the water W from the carrier C mounted on the carrier stage 11 and places the same on the delivery part 14. The wafer W placed on the delivery part 14 is picked up from the delivery part 14 by the substrate transfer device 17 of the processing station 3 and loaded into the processing unit 16.

The wafer W loaded into the processing unit 16 is processed by the respective processing unit 16. Thereafter, the processed wafer W is unloaded from the processing unit 16 by the substrate transfer device 17, and then placed on the delivery part 14. Thereafter, the processed wafer W placed on the delivery part 14 is returned to the carrier C of the carrier stage 11 by the substrate transfer device 13.

### [Configuration of Substrate Processing Apparatus]

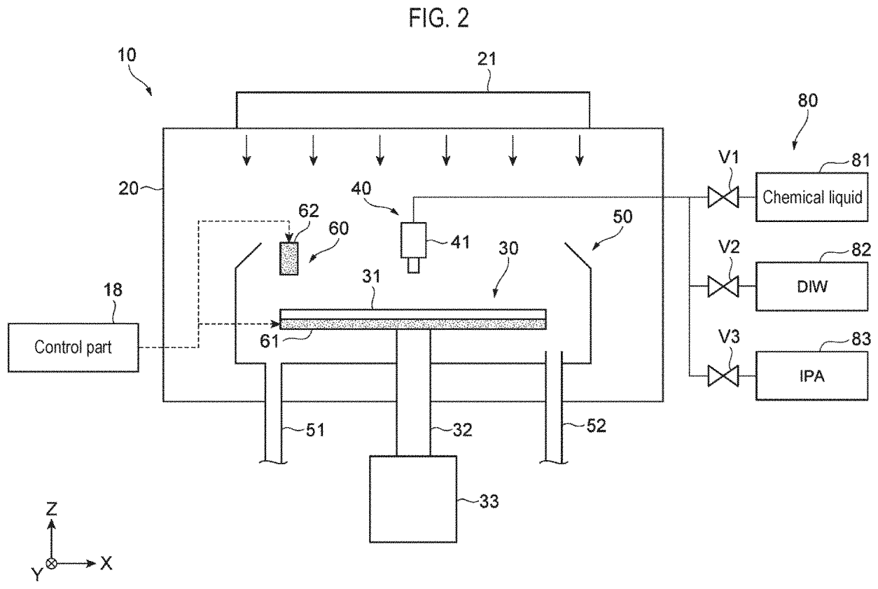

The configuration of a substrate processing apparatus 10 included in the substrate processing system 1 will be described with reference to FIG. 2. The substrate processing apparatus 10 is included in the processing unit 16 of the substrate processing system 1.

As shown in FIG. 2, the substrate processing apparatus 10 includes a chamber 20, a substrate holding mechanism 30, a processing liquid supply part 40, a collection cup 50 and a temperature adjustment part 60.

The chamber 20 accommodates the substrate holding mechanism 30, the processing liquid supply part 40 and the collection cup 50. An ITU (Fan Filter Unit) 21 is provided on a ceiling of the chamber 20. The FFU 21 has a function of forming a down-flow in the chamber 20. The FFU 21 forms the down-flow by supplying a down-flow gas, which is supplied from a down-flow gas supply pipe (not shown), into the chamber 20.

The substrate holding mechanism 30 has a function of holding the wafer W in a rotatable manner. The substrate holding mechanism 30 includes a holding part 31, a support pillar part 32 and a driving part 33. The holding part 31 holds the wafer W in a horizontal posture. The support pillar part 32 is a member extending in the vertical direction, and has a base end portion rotatably supported by the driving part 33 and a leading end portion that supports the holding part 31 in a horizontal posture. The driving part 33 rotates the support pillar part 32 around a vertical axis. The substrate holding mechanism 30 rotates the holding part 31 supported by the support pillar part 32 by rotating the support pillar part 32 using the driving part 33, thereby rotating the wafer W held by the holding part 31.

The processing liquid supply part 40 supplies a processing liquid with respect to the wafer W. The processing liquid supply part 40 is connected to a processing liquid source 80. The processing liquid supply part 40 includes a nozzle 41 configured to supply the processing liquid supplied from the processing liquid source 80 therefrom. The processing liquid source 80 includes sources corresponding to a plurality of processing liquids, and changes the processing liquid to be supplied as the processing of the wafer W progresses. The nozzle 41 is provided in a head portion of a nozzle arm (not shown) that is rotatably movable in a transverse direction (horizontal direction). In addition, it is possible to supply the processing liquid onto the wafer W while changing a position of the tip of the nozzle 41 with the rotational movement of the nozzle arm.

The processing liquid source 80 includes a chemical liquid source 81, a DIW source 82 and an IPA source 83. The chemical liquid source 81 supplies one or more types of chemical liquids used for surface treatment of the wafer W. The DIW source 82 supplies DIW (Deionized Water) used for surface rinsing of the wafer W. The IPA source 83 supplies IPA (isopropyl alcohol) with which the DIW on the front surface of the wafer W is to be replaced. The IPA is a kind of volatile drying liquid and has a lower surface tension than the DIW. Therefore, after the DIW on the front surface of the wafer W is replaced with the IPA, the IPA is removed to dry the wafer W, thereby preventing damage to a pattern on the front surface of the wafer W when the wafer W is dried. The chemical liquid source 81, the DIW source 82 and the IPA source 83 are connected to the nozzle 41 via valves V1, V2 and V3, respectively. The processing liquid supplied from the nozzle 41 onto the wafer W can be changed by switching the opening/closing of the valves V1, V2 and V3.

Although one nozzle 41 is shown in FIG. 2, a plurality of nozzles may be provided individually so as to correspond to the plurality of types of processing liquids. In some embodiments, one nozzle may be shared to supply some processing liquids.

The movement of the nozzle 41 and the supply and cutoff of the liquid from each source of the processing liquid source 80 are controlled by the controller 18 described above.

The collection cup 50 is disposed so as to surround the holding part 31, and collects the processing liquid scattered from the wafer W by the rotation of the holding part 31. A liquid drain port 51 is formed at a bottom of the collection cup 50. The processing liquid collected by the collection cup 50 is discharged from the liquid drain port 51 outward of the processing unit 16. Further, an exhaust port 52 for discharging a gas supplied from the FFU 21 outward of the processing unit 16 therethrough is formed in the bottom of the collection cup 50.

The temperature adjustment part 60 has a function of controlling the temperature of the front surface of the wafer W held on the holding part 31. In the substrate processing apparatus 10 shown in FIG. 2, the temperature adjustment part 60 includes a first temperature adjuster 61 that controls the temperature of the entire front surface of the wafer W at the side of a back surface of the holding part 31, and a second temperature adjuster 62 of a line type provided at the side of the front surface of the wafer W. The first temperature adjuster 61 and the second temperature adjuster 62 perform heating or cooling, respectively, to control a temperature distribution on the front surface of the wafer W. That is to say, the first temperature adjuster 61 and the second temperature adjuster 62 function a substrate heating part or a substrate cooling part.

The first temperature adjuster 61 is provided at the side of the back surface of the wafer W and controls the temperature of the entire wafer W. In an embodiment, although the first temperature adjuster 61 performs the temperature control of the wafer W on the basis of surface, the first temperature adjuster 61 may be configured such that the temperature distribution on the front surface of the wafer W has deviation instead of performing heating or cooling of the wafer W at a uniform temperature. For example, the first temperature adjuster 61 may be partitioned into a plurality of areas to perform a so-called multi-channel control in which independent temperature control for different areas is performed to heat the wafer W to different heating temperatures at different positions. Further, the use of the multi-channel control may provide a predetermined gradient to the temperature of the front surface of the wafer W. When the wafer W is heated by the first temperature adjuster 61, a hot plate may be used as the first temperature adjuster 61. Further, when the wafer W is cooled down by the first temperature adjuster 61, a cooling plate may be used as the first temperature adjuster 61. However, the configuration of the first temperature adjuster 61 is not limited thereto.

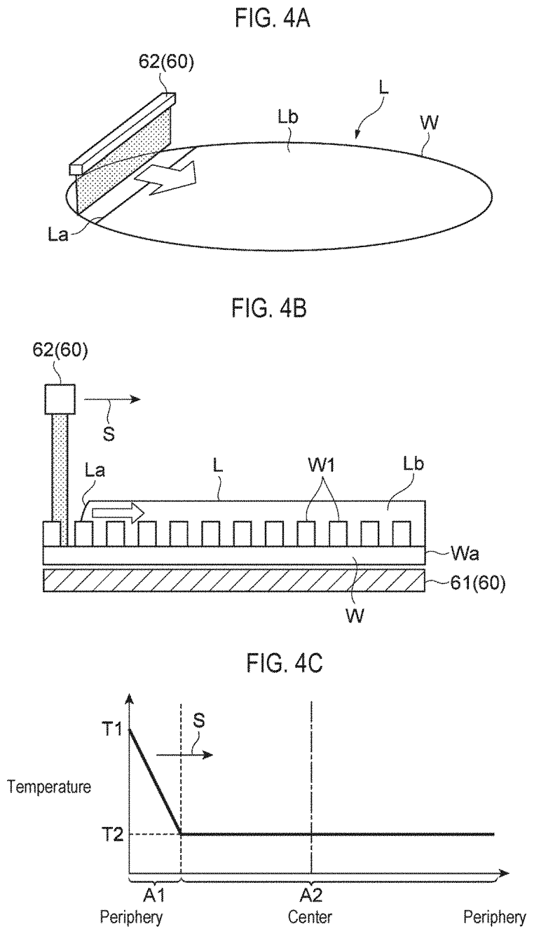

The second temperature adjuster 62 is a line-type heating source or a line-type cooling source, which is separated from the front surface of the wafer W by a predetermined distance and extends in a transverse direction (horizontal direction) (see also FIG. 4A). FIG. 2 shows a state in which the second temperature adjuster 62 is disposed such that a longitudinal direction thereof is the Y-axis direction. In addition, the second temperature adjuster 62 is movable in the transverse direction (horizontal direction) which is a direction intersecting (for example, orthogonal to) the longitudinal direction of the second temperature adjuster 62. The second temperature adjuster 62 shown in FIG. 2 can move along the X-axis direction in all areas overlapping the front surface of the water W on the holding part 31 in a plan view. With this configuration, it is possible to heat or cool down a specific area of the wafer W (an area adjacent to the second temperature adjuster 62). When the wafer W is heated by the second temperature adjuster 62, a laser or lamp may be used as the second temperature adjuster 62. Further, when the wafer W is cooled down by the second temperature adjuster 62, an air flow (cooled gas) may be used as the second temperature adjuster 62. However, the configuration of the second temperature adjuster 62 is not limited thereto.

The adjustment of the heating temperature or the cooling temperature by the first temperature adjuster 61 and the second temperature adjuster 62, the movement of the second temperature adjuster 62 and the like are controlled by the controller 18 described above.

### [Substrate Processing Method]

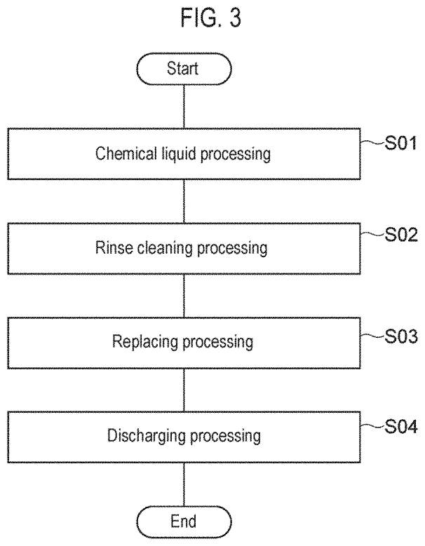

Contents of liquid processing implemented using the substrate processing apparatus 10 will be described with reference to FIG. 3.

First, when the wafer W loaded into the processing unit 16 by the substrate transfer device 17 is held by the holding part 31 of the substrate holding mechanism 30, the nozzle 41 is moved to a processing position on the wafer W. Then, a chemical liquid process is performed by rotating the wafer W at a predetermined rotation speed and supplying a chemical liquid from the nozzle 41 (step S01). At this time, the support pillar part 32 and the driving part 33 shown in FIG. 2 correspond to a rotation mechanism that rotates the wafer W held by the holding part 31.

Subsequently, a rinse cleaning process is performed in which the processing liquid supplied from the nozzle 41 is switched to DIW for cleaning (step S02). Specifically, while the wafer W is being rotated, DIW is supplied onto the water W on which a liquid film of the chemical liquid is formed. By supplying the DIW, residues adhering to the wafer W are washed away.

After the rinse cleaning process is performed for a predetermined period of time, the supply of the DIW from the nozzle 41 is ceased. Subsequently, a replacing process is performed in which an IPA is supplied from the nozzle 41 with respect to the front surface of the rotating wafer W to replace the DIW on the front surface of the wafer W with the IPA (step S03: a drying liquid supplying step). As the IPA is supplied onto the front surface of the wafer W, an IPA liquid film is formed on the front surface of the wafer W. Thus, the DIW remaining on the front surface of the water W is replaced with the IPA.

After the DIW on the front surface of the wafer W is sufficiently replaced with the IPA, the supply of the IPA onto the wafer W is ceased. Then, a discharging process is performed in which the IPA remaining on the front surface of the wafer W is discharged from the front surface of the wafer W (step S04: a discharging step). By discharging the IPA from the front surface of the wafer W, the front surface of the wafer W remains dried. In addition, in the substrate processing apparatus 10, the discharging of the IPA from the front surface of the wafer W is promoted by causing deviation in the temperature of the front surface of the wafer W by the temperature adjustment part 60, which will be described in detail later.

When the front surface of the wafer W is dried, the liquid processing on the wafer W is completed. The wafer W is unloaded from the substrate processing apparatus 10 in a procedure opposite to that at the time of loading.

### [Discharging Process]

An IPA discharging process the IPA using the temperature adjustment part 60 will be described with reference to FIGS. 4A to 4C. FIG. 4A is a perspective view for explaining the operation of the second temperature adjuster 62 disposed above the front surface of the wafer W. FIG. 4B is a view for explaining the temperature control of the wafer W by the first temperature adjuster 61 and the second temperature adjuster 62. As shown in FIG. 4B, a predetermined pattern W1 (for example, a resist pattern) is formed on the front surface of the wafer W. FIG. 4C is a view for explaining the temperature of the front surface of the wafer W.

Prior to the IPA discharging process, an IPA liquid film L is formed so as to cover the front surface of the wafer W. In the example shown in FIGS. 4A to 4C, the first temperature adjuster 61 functions as a substrate cooling part that cools the back surface of the water W to a predetermined temperature. The front surface of the wafer W is cooled down to a constant temperature by the first temperature adjuster 61. The second temperature adjuster 62 functions as a substrate heating part that heats a predetermined position on the front surface of the wafer W in the vicinity of the front surface of the wafer W. When the IPA is discharged, the second temperature adjuster 62 is disposed close to an end portion of the wafer W, as shown in FIG. 4B. Then, a surface of the end portion of the wafer W is heated by the second temperature adjuster 62.

As a result, as shown in FIG. 4C, the temperature of the front surface of the wafer W is set such that a temperature T1 at the end portion (outer periphery) to which the second temperature adjuster 62 is disposed close is higher than a temperature T2 at other portions. A drying target area A1 in which the temperature T1 is changed to the temperature T2 is formed between the end portion of the wafer W that has the temperature T1 and an unprocessed area A2 that has the temperature T2. That is to say, the front surface of the wafer W includes the drying target area A1 and the unprocessed area A2 formed adjacent to the drying target area A1. In other words, a temperature of an edge portion La near the drying target area A1 in the IPA liquid film L is higher than that of a remaining portion Lb corresponding to the unprocessed area A2 in the IPA liquid film L. Therefore, a temperature difference occurs between the edge portion La and the remaining portion Lb. Accordingly, in the drying target area A1, the IPA liquid film L is aggregated toward the unprocessed area A2 having the relatively low temperature.

In the drying target area A1, since the temperature of the front surface of the wafer W is higher than that of the other area having the temperature T2, evaporation (volatilization) of IPA from the IPA liquid film L is promoted. As a result, a film thickness of the IPA liquid film L in the drying target area A1 is smaller than that of the unprocessed area. A2 (the area having the temperature T2). As a result, a difference in surface tension occurs between the IPA liquid film L in the drying target area A1 and the IPA liquid film L in the unprocessed area A2. The surface tension of the IPA liquid film L in the drying target area A1 is smaller than that in the unprocessed area A2. As a result, a so-called Marangoni convection is generated by which the edge portion La of the IPA liquid film L in the drying target area A1 is pulled toward the unprocessed area A2 (the right side in FIG. 4). Due to a force generated by such a Marangoni convection, the edge portion La of the IPA liquid film L moves toward the lower temperature-side area.

At this time, as shown in FIG. 4B, when the second temperature adjuster 62 is moved in a direction indicated by an arrow S, the drying target area A1 moves from the position shown in FIG. 4C in the arrow direction S. By moving the second temperature adjuster 62 in accordance with the aggregation rate of the IPA liquid film L (the movement speed of the edge portion La of the IPA liquid film L), the aggregation of the IPA liquid film L by the Marangoni convection can be progressed, thus moving the IPA on the front surface of the wafer W in the arrow direction S. Accordingly, it is possible to discharge the IPA from the front surface of the wafer W at an end portion Wa of the wafer W at the downstream side along the arrow direction S.

On the front surface of the wafer W, an area to be subjected to the drying process of the IPA liquid film L is the “drying target area A1”. On the other hand, on the front surface of the wafer W, an area not to be subjected to the drying process of the IPA liquid film L is the “unprocessed area A2”. In the example shown in FIGS. 4A to 4C, the drying target area A1 is an area on the front surface of the wafer W, which has been heated by the second temperature adjuster 62, namely an area where a temperature gradient that changes from the temperature T1 to the temperature 12 is generated. As described above, in the drying target area A1, as the edge portion La of the IPA liquid film L is pulled toward the unprocessed area A2 by the Marangoni convection, the end portion of the IPA liquid film L moves. Accordingly, by controlling the position of the drying target area A1 so that a temperature gradient is formed on the front surface of the wafer W between the drying target area and the other areas, the aggregation of the IPA on the front surface of the wafer W can be progressed.

### Actions/Effects

As described above, in the substrate processing apparatus 10, a temperature difference is formed between the drying target area A1 and the unprocessed area A2 on the front surface of the wafer W by using the temperature control of the front surface of the wafer W by the temperature adjustment part 60. Specifically, a temperature difference is generated in the IPA liquid film L so that the temperature of the edge portion La of the IPA liquid film L is high and the temperature of the remaining portion Lb of the IPA liquid film L is low. As a result, the Marangoni convection occurs at the edge portion La of the IPA liquid film L. Therefore, the IPA is discharged from the front surface of the wafer W while aggregating the IPA in a predetermined direction (specifically, toward the side where the temperature is low) on the front surface of the wafer W. Thus, by adopting a configuration in which IPA is discharged from the front surface of the wafer W using the aggregation of IPA based on the Marangoni convection, it is possible to prevent the pattern on the front surface of the wafer W from collapsing when removing the IPA from the front surface of the wafer W.

As a method of removing IPA from the front surface of the wafer W, a method of moving the IPA to the outer peripheral side of the wafer W by virtue of a centrifugal force generated when rotating the wafer W has been conventionally used. In this case, the IPA on the front surface of the wafer W flows outward due to the centrifugal force. However, when the IPA is moved due to an external force in this way, a boundary layer having a very thin liquid thickness may be formed at the end portion of the IPA liquid film. The boundary layer is an area where the IPA cannot be moved by the external force. Thus, the front surface of the wafer W is dried only by the evaporation of the IPA. At this time, the evaporation rate of the IPA is not uniform on the front surface of the wafer W. In particular, since a number of patterns W1 are formed on the front surface of the wafer W, liquid level heights of the IPA tend to vary depending on the shape of the patterns W1 and the like. When the evaporation of IPA proceeds in a state where the liquid level heights of the IPA are different, a difference in stress derived from the liquid level heights affects the patterns W1, which may damage to the pattern W1, such as the pattern collapse.

In contrast, in the substrate processing apparatus 10, the IPA on the front surface of the wafer W is aggregated using the Marangoni convection caused by the temperature gradient as described above. That is to say, when the IPA is moved by virtue of the surface tension difference rather than being moved due to the external force, it is possible to prevent the boundary layer from being formed at the edge portion La of the IPA liquid film L. That is to say, it is possible to eliminate an area where the evaporation-based drying is performed, which makes it possible to prevent damage to the pattern. W1, such as the pattern collapse, when removing the IPA. In recent years, the pattern W1 formed on the front surface of the wafer W has an increased aspect ratio. This increases a rick of increasing the pattern collapse. However, the removal of the IPA using the Marangoni convection makes it possible to reduce the occurrences rate of the pattern collapse. In addition, in the temperature gradient on the front surface of the wafer W, it may not be required that the temperature at the side where the IPA liquid film L exists is low and the temperature at the side where the IPA liquid film L does not exist (at the side where the wafer W is exposed) is high. Further, a temperature gradient may not be formed in the unprocessed area A2 (the unprocessed area) as long as a desired temperature difference can be generated between the drying target area and the other area (the unprocessed area).

The temperature of the front surface of the wafer W controlled by the temperature adjustment part 60 may be controlled such an extent that the volatilization of IPA is not promoted, in order to generate the Marangoni convection in the IPA, the temperature of the front surface of the wafer W may be higher than room temperature (about 23 degrees C.). For example, the temperature adjustment part 60 can be controlled so that the temperature of the front surface of the wafer W is 30 degrees C. or higher. If the temperature of the front surface of the wafer W becomes too high, the volatilization of the IPA may be promoted more than the movement due to the aggregation of the IPA. Thus, there is a high possibility that the pattern is damaged.

As shown in FIGS. 4A to 4C, in the substrate processing apparatus 10, the second temperature adjuster 62 is moved horizontally in the arrow direction S from the end portion of one side of the wafer W. Thus, the IPA liquid film L is aggregated in the arrow direction S and is discharged from the end portion Wa toward the downstream side in the arrow direction S. In this way, the IPA moves along the arrow direction S on the front surface of the wafer W. In order to promote the movement of the IPA, the wafer W on the holding part 31 may be inclined slightly (by about 0.1 to 1 degrees) so that the end portion Wa is oriented downward. An example of a method of inclining the wafer W on the holding part 31 may include a method of causing a so-called axis shift by moving the position of the support pillar part 32 configured to support the holding part 31 in the transverse direction. In this manner, the wafer W may be slightly inclined to promote the discharging of the IPA from the end portion Wa of the wafer W.

The movement of the second temperature adjuster 62 and the cooling temperature by the first temperature adjuster 61 are changed by the control of the controller 18. The controller 18 may control each adjuster of the temperature adjustment part 60 by executing a predetermined program based on liquid properties of the IPA. In addition, the controller 18 may perform a control to change the operation of each adjuster of the temperature adjustment part 60 based on, for example, information on the state of the front surface of the wafer W, which is acquired by a camera installed in the substrate processing apparatus 10 to observe the front surface of the wafer W.

### <First Modification>

Next, a modification of the temperature adjustment part 60 will be described. As described above, when a temperature gradient is formed in the vicinity of the edge portion La of the IPA liquid film L so that the temperature at the side where the IPA liquid film L exists is low and the temperature at the side where the IPA liquid film L does not exist (the side at which the wafer W is exposed) is high, the Marangoni convection occurs in the edge portion La of the IPA liquid film L. By generating this Marangoni convection, the IPA liquid film L is aggregated by virtue of a surface tension without forming a boundary layer. Accordingly, the configuration of the temperature adjustment part 60 may be changed as appropriate as long as the temperature gradient as described above can be formed on the front surface of the wafer W.

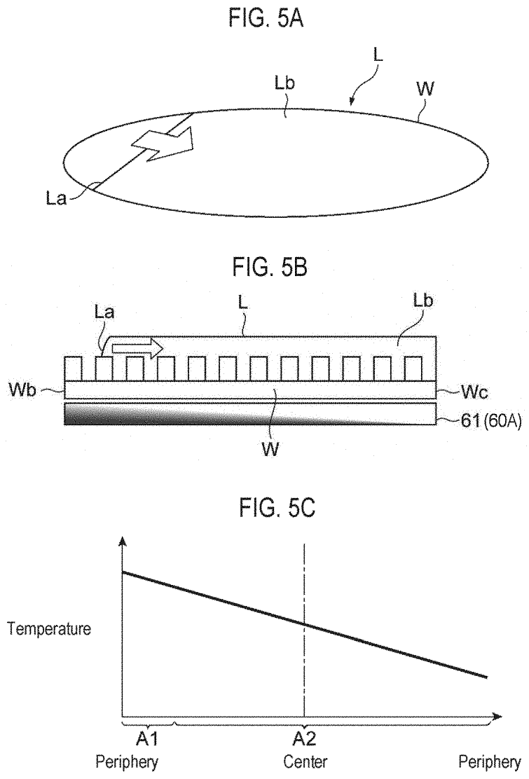

FIGS. 5A to 5C are views showing a temperature adjustment part 60A according to a first modification. FIGS. 5A to 5C correspond to FIGS. 4A to 4C, respectively. The temperature adjustment part 60A is different from the temperature adjustment part 60 in the following points. Specifically, in the temperature adjustment part 60A, a temperature gradient is formed on the front surface of the wafer W1 by changing a heating temperature of the first temperature adjuster 61 provided at the side of the back surface of the wafer W at each position. That is to say, the second temperature adjuster 62 is not used.

In FIG. 5B, a heating temperature of the first temperature adjuster 61 at each position is indicated by gradation. That is to say, the heating temperature is controlled by the first temperature adjuster 61 so that the heating temperature is increased at a left portion Wb of the wafer W in FIG. 5B and is decreased toward a right end portion Wc of the wafer W. As a result, as shown in FIG. 5C, in the temperature of the front surface of the wafer W, a temperature gradient from the left end portion Wb toward the right end portion Wc is formed as a whole. That is to say, in the example shown in FIGS. 5A to 5C, the temperature gradient is formed in both the drying target area A1 and the unprocessed area A2.

As a result, as shown in FIG. 5B, a Marangoni convection is generated in the IPA liquid film L from the side of the end portion Wb of the water W, and is moved toward the end portion Wc. Since the temperature of the front surface of the wafer W has the temperature gradient as a whole, even when the edge portion La of the IPA liquid film L moves toward the end portion Wc, the edge portion La exists on the drying target area A1. Therefore, the aggregation and movement of the IPA liquid film L by the Marangoni convection are continued. That is to say, the temperature gradient formed on the entire front surface of the wafer W functions as a temperature gradient having a lower temperature at the side where the IPA liquid film L exists, and a higher temperature at the side where the IPA liquid film L does not exist (at the side of the end portion Wb where the wafer W is exposed). As a result, the IPA liquid film L moves toward the end portion Wc and is discharged from the end portion Wc.

In this manner, by controlling the heating temperature of the wafer W at different places using the first temperature adjuster 61, it is possible to form a temperature gradient on the front surface of the wafer W without having to use a combination with the second temperature adjuster 62. Therefore, this temperature gradient may be used to control the movement and discharging of the IPA liquid film L. Even with such a configuration, it is possible to reduce the occurrence rate of pattern collapse.

### <Second Modification>

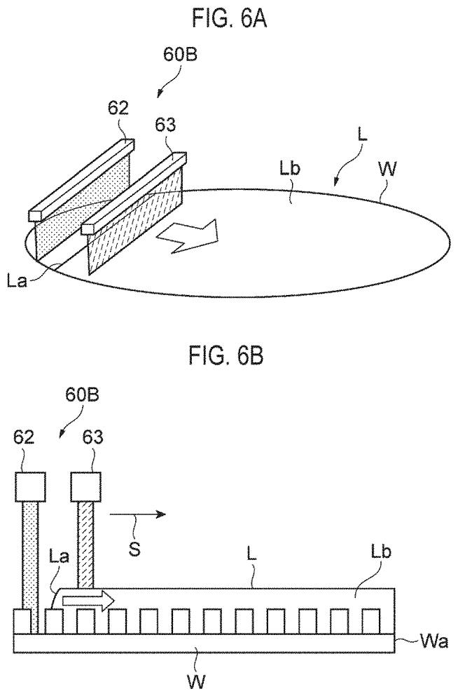

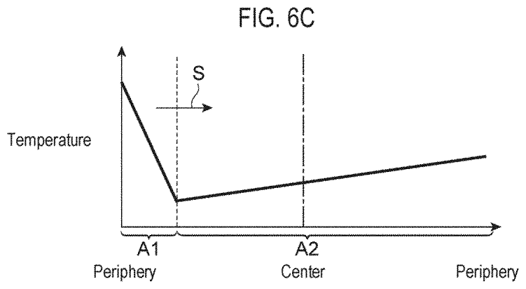

FIGS. 6A to 6C are views showing a temperature adjustment part 60B according to a second modification. FIGS. 6A to 6C correspond to FIGS. 4A to 4C, respectively. The temperature adjustment part 60B is different from the temperature adjustment part 60 in the following points. Specifically, in the temperature adjustment part 60B, a temperature gradient is formed on the front surface of the wafer W by using a third temperature adjuster 63 disposed in parallel with the second temperature adjuster 62, instead of using the first temperature adjuster 61 provided at the side of the back surface of the wafer W. That is to say, the first temperature adjuster 61 is not used.

In the temperature adjustment part 60B, as with the second temperature adjuster 62, the third temperature adjuster 63 may also be a line-type heating source or a line-type cooling source that extends in the transverse direction (horizontal direction). In the temperature adjustment part 60B, the second temperature adjuster 62 is used as the heating source, and the third temperature adjuster 63 is used as the cooling source. In addition, as shown in FIGS. 6A and 6B, the second temperature adjuster 62 and the third temperature adjuster 63 are arranged to extend in parallel to each other with the edge portion La of the IPA liquid film L interposed therebetween. The third temperature adjuster 63 is located at the side of the IPA liquid film L.

As a result, as shown in FIG. 6C, the drying target area A1 is formed between the second temperature adjuster 62 and the third temperature adjuster 63. Since the third temperature adjuster 63 serving as a cooling source is disposed at the side of the IPA liquid film L, a temperature gradient having a lower temperature at the side where the IPA liquid film L exists and a higher temperature at the side where the IPA liquid film L does not exist (at the side where the wafer W is exposed) is formed in the drying target area A1. Accordingly, the edge portion La of the IPA liquid film L moves toward the third temperature adjuster 63.

At this time, when the second temperature adjuster 62 and the third temperature adjuster 63 are moved in an arrow direction S, as shown in FIG. 6B, in accordance with the movement of the edge portion La, the drying target area A1 moves in the arrow direction S from a position shown in FIG. 6C. By moving the second temperature adjuster 62 and the third temperature adjuster 63 in accordance with the aggregation rate of the IPA liquid film L (the movement speed of the edge portion La of the IPA liquid film L), the aggregation of the IPA liquid film L by the Marangoni convection in the edge portion La can proceed. As a result, the IPA on the front surface of the wafer W can be moved in the arrow direction S. Accordingly, the IPA can be discharged from the front surface of the wafer W at the end portion Wa of the wafer W, which is a downstream side, along the arrow direction S.

In this manner, even in the case where the temperature adjustment part 60B is constituted by combining the second temperature adjuster 62 and the third temperature adjuster 63, both of which are of a liner shape, it is possible to form a temperature gradient on the front surface of the wafer W. Therefore, this temperature gradient may be used to control the movement and discharging of the IPA liquid film L. Even with such a configuration, it is possible to reduce the occurrence rate of pattern collapse.

### Second Embodiment

Next, a second embodiment of the temperature adjustment part will be described. The case where the movement of the IPA liquid film L in one direction (for example, the arrow direction S shown in FIG. 4B) is promoted using the IPA-based Marangoni convection caused by the temperature gradient on the front surface of the wafer W has been described in the first embodiment. Therefore, in the first embodiment, the IPA is discharged from one end portion of the water W (for example, the end portion Wa shown in FIG. 4B). In contrast, a case where the movement of the IPA liquid film L from the center of the wafer W to the outer peripheral side thereof is promoted using the IPA-based Marangoni convection caused by the temperature gradient on the front surface of the wafer W will be described in the second embodiment. Since the IPA liquid film L is moved from the center to the outer peripheral side of the water W, the IPA is discharged from any one of the outer peripheries of the wafer W.

The point that a temperature gradient is formed on the front surface of the wafer W is the same as in the first embodiment. That is to say, a temperature gradient is formed in the vicinity of the end portion of the IPA liquid film L so that a temperature at the side where the IPA liquid film L exists is low and a temperature at the side where the IPA liquid film L does not exist (the side where the wafer W is exposed) is high. The Marangoni convection occurs in the edge portion La of the IPA liquid film L.

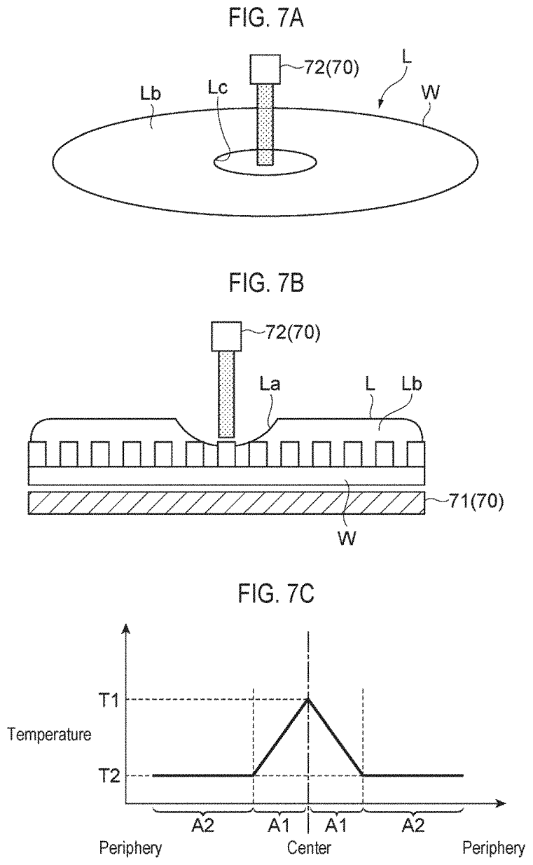

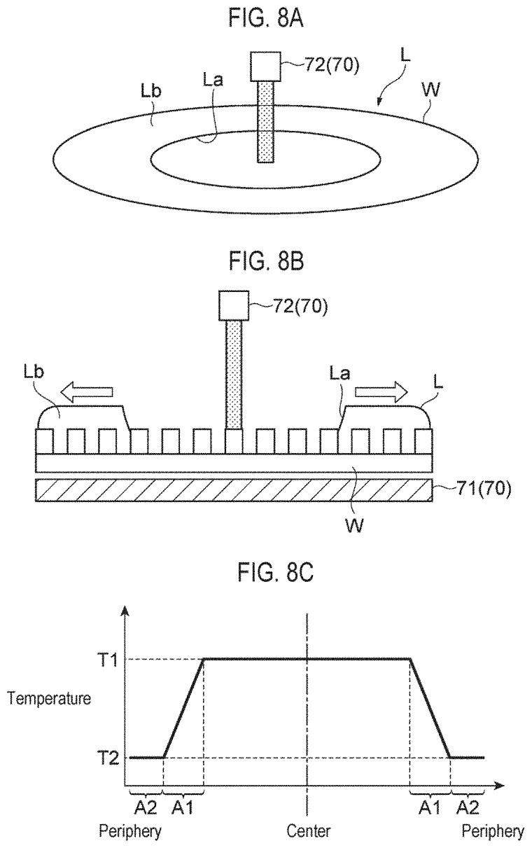

FIGS. 7A to 7C and FIGS. SA to 8C are views showing a temperature adjustment part 70 according to the second embodiment. FIGS. 7A to 7C and FIGS. 8A to 8C correspond to FIGS. 4A to 4C, respectively.

The temperature adjustment part 70 includes a first temperature adjuster 71 provided at the side of the back surface of the water W and a second temperature adjuster 72 provided at the side of the front surface of the wafer W.

The first temperature adjuster 71 has the same configuration as the first temperature adjuster 61 of the temperature adjustment part 60. That is to say, the first temperature adjuster 71 is provided at the side of the back surface of the wafer W to control the temperature of the entire wafer W. The first temperature adjuster 71 may be also partitioned into a plurality of areas to perform a so-called multi-channel control in which independent temperature control for different areas is performed, so that the temperature of the front surface of the wafer W has a predetermined gradient.

The second temperature adjuster 72 is a spot-type heating source that is provided in an area including the center of the wafer W and is separated from the front surface of the wafer W by a predetermined distance (see also FIG. 7A). The second temperature adjuster 72 heats the area including the center of the front surface of the wafer W. A laser or a lamp may be used as the second temperature adjuster 72. However, the configuration of the second temperature adjuster 72 is not limited thereto. The “area including the center of the front surface of the wafer W” that is heated by the second temperature adjuster 72 refers to an area including the center of the wafer W and having a diameter smaller than that of the wafer W. The diameter of the area including the center of the front surface of the wafer W may be 30% or less of the diameter of the wafer W.

An IPA discharging process using the temperature adjustment part 70 will be described. Before the IPA discharging process is performed, an IPA liquid film L is formed so as to cover the front surface of the wafer W. In the example shown in FIGS. 7A to 7C, the first temperature adjuster 71 functions as a substrate cooling part that cools down the back surface of the wafer W to a predetermined temperature. The front surface of the wafer W is cooled down to a constant temperature by the first temperature adjuster 71.

The second temperature adjuster 72 functions as a substrate heating part that heats the vicinity of the center of the wafer W from the side of the front surface of the wafer W. When the IPA is discharged, as shown in FIG. 713, the second temperature adjuster 72 is disposed near the center of the wafer W and heats a surface near the center of the wafer W.

As a result, as shown in FIG. 7C, a temperature T1 of the area including the center of the front surface of the wafer W is higher than a temperature T2 at the outer peripheral side that is away from the second temperature adjuster 72. Accordingly, a drying target area A1 in which the temperature T1 is changed to the temperature T2 is formed between the area including the center of the wafer W and having the temperature and an unprocessed area A2 having the temperature T2. When the drying target area A1 is formed, aggregation of the IPA liquid film L toward the area having a lower temperature proceeds in the drying target area A1. In addition, in the drying target area A1, the temperature gradually decreases toward the outer peripheral side, centered at the temperature T1 of the area including the center of the wafer W.

A Marangoni convection derived from a difference in surface tension of the IPA liquid film L occurs in the drying target area A1. Due to a force generated by the Marangoni convection, an edge portion La (inner peripheral edge) of the IPA liquid film L moves toward the lower temperature-side area, namely the outer peripheral side of the wafer W.

When the aggregation of the IPA liquid film L proceeds, the edge portion La of the IPA liquid film L gradually moves to the outer peripheral side, as shown in FIGS. 8A and 813. On the one hand, if the cooling of the wafer W by the first temperature adjuster 71 and the heating of the area including the center of the wafer W by the second temperature adjuster 72 are continued, the surface temperature of the area including the center of the wafer W from which the IPA liquid film L has been removed (namely, dried) is constant at the temperature T1. On the other hand, an area where the IPA liquid film L remains at outer peripheral side is maintained at the temperature T2. As a result, as shown in FIG. 8C, an annular drying target area A1 is formed in the vicinity of the edge portion La of the IPA liquid film L, namely in an area where a film thickness of the IPA liquid film L changes. Therefore, the edge portion La moves to the outer peripheral side of the wafer W while the Marangoni convection is formed in the vicinity of the edge portion La of the IPA liquid film L. Moreover, with the movement of the edge portion La, the drying target area A1 also moves to the outer peripheral side. Thus, by continuing the movement of the edge portion La of the IPA liquid film L using the Marangoni convection, it is possible to discharge the IPA from the front surface of the wafer W in the outer periphery of the wafer W.

In this manner, even when the temperature adjustment part 70 is used, the drying target area A1 can be formed by using the temperature control of the front surface of the wafer W. That is to say, a temperature gradient is formed in the vicinity of the edge portion La of the IPA liquid film L, so that the temperature at the side where the IPA liquid film L exists is low and the temperature at the side where the IPA liquid film L does not exist (at the side where the wafer W is exposed) is high. This generates the Marangoni convection in the edge portion La of the IPA liquid film L. As a result, the IPA can be discharged from the front surface of the wafer W while aggregating the IPA toward the side where the temperature of the front surface of the wafer W is lower. Accordingly, it is possible to prevent pattern collapse of the front surface of the wafer W when removing the IPA from the front surface of the wafer W.

In some embodiments, in the temperature adjustment part 70, the healing temperature of the area including the center of the wafer W by the second temperature adjuster 72 may be gradually changed as the edge portion La of the IPA liquid film L moves toward the outer periphery. That is to say, the healing temperature by the second temperature adjuster 72 may be changed so that the temperature of the front surface of the wafer W in an area where the edge portion La is formed falls within a temperature range in which the Marangoni convection due to the IPA liquid film is likely to occur. In this case, it is considered that the surface temperature of the area including the center of the wafer W is higher than the temperature T1. The temperature of the front surface of the wafer W may be appropriately changed as long as the wafer W is not affected.

### <Third Modification>

Next, a modification of the temperature adjustment part 70 will be described. As described above, when the temperature gradient is formed in the vicinity of the edge portion La of the IPA liquid film L, so that the temperature at the side where the IPA liquid film L exists is low and the temperature at the side where the IPA liquid film L does not exist (at the side where the wafer W is exposed) is high, the Marangoni convection is generated in the edge portion La of the IPA liquid film L. By generating this Marangoni convection, the IPA liquid film L is aggregated by virtue of a surface tension without forming a boundary layer. Accordingly, the configuration of the temperature adjustment part 70 may be changed as appropriate as long as the temperature gradient as described above can be formed on the front surface of the wafer W.

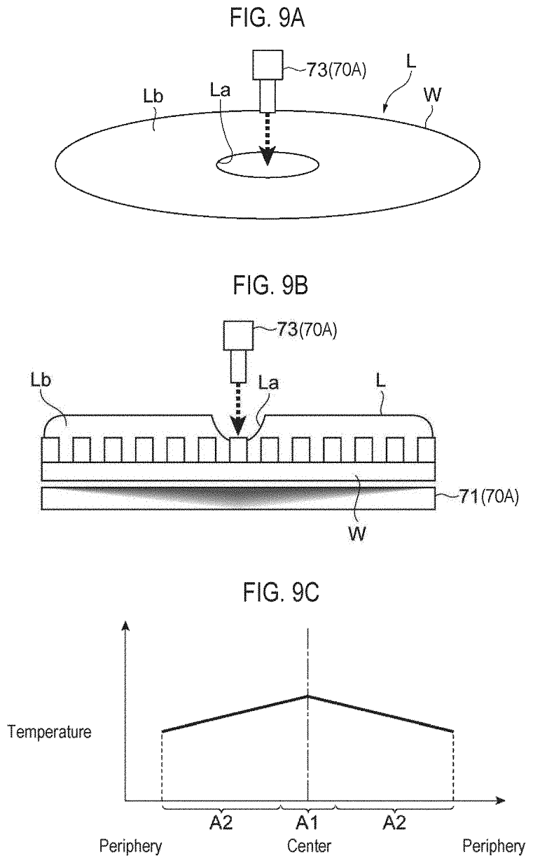

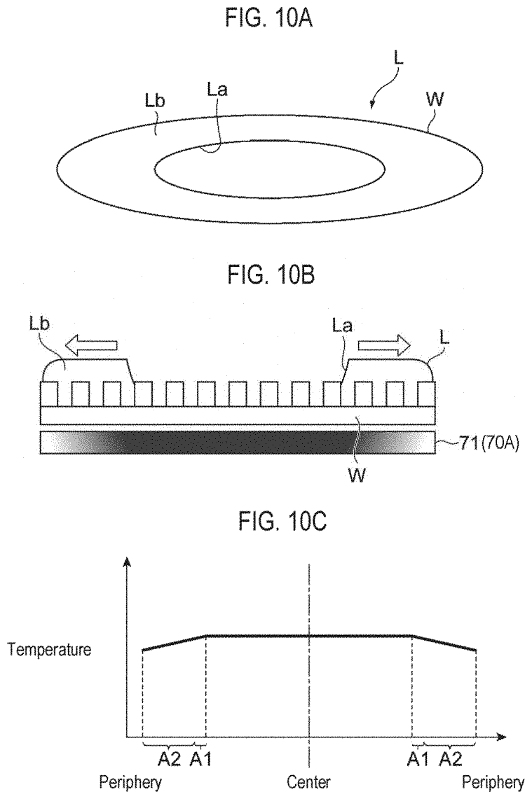

FIGS. 9A to 9C and FIGS. 10A to 10C are views showing a temperature adjustment part 70A according to a third modification. FIGS. 9A to 9C and FIGS. 10A to 10C correspond to FIGS. 4A to 4C, respectively.

The temperature adjustment part 70A is different from the temperature adjustment part 70 in the following points. Specifically, in the temperature adjustment part 70A, a temperature gradient is formed on the front surface of the wafer W by changing a heating temperature of the first temperature adjuster 71 provided at the side of the back surface of the wafer W at each position. That is to say, the second temperature adjuster 72 is not used.

In FIG. 9B, the heating temperature of the first temperature adjuster 71 at each position is indicated by gradation. That is to say, the heating temperature is controlled by the first temperature adjuster 71 so that the heating temperature in the vicinity of the center of the wafer W is high and is gradually decreased toward the outer periphery. As a result, as shown in FIG. 9C, the temperature of the front surface of the wafer W has a temperature gradient from the vicinity of the center of the wafer W toward the outer periphery. That is to say, the temperature gradient is formed on the entire surface of the wafer W. In other words, in the example shown in FIGS. 9A to 9C, the temperature gradient is formed in both the drying target area A1 and the unprocessed area A2.

The temperature adjustment part 70A includes a gas injecting part 73 configured to inject a gas onto the front surface of the wafer W, instead of the second temperature adjuster 72. The gas injecting part 73 injects a gas such as nitrogen or the like onto the front surface of the wafer W. By injecting the gas, an opening can be formed in the IPA liquid film L near the center of the wafer W.

An IPA discharging process using the temperature adjustment part 70A will be described. Before the IPA discharging process is performed, an IPA liquid film L is formed so as to cover the front surface of the wafer W. As described above, the temperature of the front surface of the wafer W is set to gradually decrease from the vicinity of the center of the wafer W toward the outer periphery thereof by the first temperature adjuster 71.

Here, the opening of the IPA liquid film L is formed in the vicinity of the center of the wafer W by the gas injecting part 73, and the wafer W is exposed in the vicinity of the center. That is to say, a drying process of the IPA liquid film L in the vicinity of the center of the wafer W is performed. Therefore, an area in the vicinity of the center of the wafer W is a drying target area A1 and an area on the outer peripheral side of the drying target area A1 is an unprocessed area A2. As a result, an edge portion La (inner peripheral edge) of the IPA liquid film L is formed at the center of the wafer W. When the edge portion La of the IPA liquid film L is formed, aggregation of the IPA liquid film L toward an area having a lower temperature proceeds using the temperature gradient formed on the entire surface of the wafer W. As described above, as a Marangoni convection derived from a difference in surface tension of the IPA liquid film L occurs in the drying target area A1, the edge portion La (inner peripheral edge) of the IPA liquid film L moves toward the lower temperature-side area, namely the outer periphery of the wafer W.

When the aggregation of the IPA liquid film L proceeds, the edge portion La of the IPA liquid film L gradually moves to the outer peripheral side, as shown in FIGS. 10A and 109. When the heating of the wafer W by the first temperature adjuster 71 is continued, the surface temperature in the vicinity of the center of the wafer W from which the IPA liquid film L has been removed (namely, dried) is constant at a predetermined temperature. On the other hand, an area where the IPA liquid film L remains at the outer peripheral side is in a state where the temperature gradient remains. Therefore, the edge portion La moves toward the outer periphery of the wafer W while the Marangoni convection is formed in the vicinity of the edge portion La of the IPA liquid film L. That is to say, with the movement of the edge portion La, the annular drying target area A1 moves toward the outer periphery. Thus, by continuing the movement of the edge portion La of the IPA liquid film L by the Marangoni convection, the IPA can be discharged from the front surface of the wafer W in the outer periphery of the wafer W.

In this manner, even when the temperature adjustment part 70A is used, the drying target area A1 can be formed by using the temperature control of the front surface of the wafer W. That is to say, the temperature gradient is formed in the vicinity of the edge portion La of the IPA liquid film L, so that the temperature at the side where the IPA liquid film L exists is low and the temperature at the side where the IPA liquid film L does not exist (at the side where the wafer W is exposed) is high. This generates the Marangoni convection in the edge portion La of the IPA liquid film L. As a result, the IPA can be discharged from the front surface of the wafer W while aggregating the IPA toward the side where the temperature of the front surface of the wafer W is low. Accordingly, it is possible to prevent pattern collapse of the front surface of the wafer W when removing the IPA from the front surface of the wafer W.

In some embodiments, in the temperature adjustment part 70A, the heating temperature by the first temperature adjuster 71 may be gradually changed as the edge portion La of the IPA liquid film L moves toward the outer periphery. That is to say, the heating temperature by the first temperature adjuster 71 may be changed so that the temperature of the front surface of the wafer W in an area where the edge portion La is formed falls within a temperature range in which the Marangoni convection due to the IPA liquid film is likely to occur.

Further, in the temperature adjustment part 70A, the heating temperature is controlled by the first temperature adjuster 71 so that the heating temperature in the vicinity of the center of the wafer W is high and is gradually decreased toward the outer periphery. However, a method of heating the wafer W by the first temperature adjuster 71 is not particularly limited as long as the drying target area A1 can be formed in the area where the edge portion La of the IPA liquid film L is formed. For example, even in a case where the first temperature adjuster 71 has not a shape corresponding to the entire surface of the wafer W but is disposed only in the vicinity of the center of the wafer W, an annular drying target area A1 can be formed on the front surface of the wafer W by controlling the heating temperature. Accordingly, the drying target area A1 can be used to control the formation of Marangoni convection in the edge portion La of the IPA liquid film L and the movement of the IPA liquid film L.

### [Others]

It should be noted that the embodiments disclosed herein are exemplary in all respects and are not restrictive. The above-described embodiments may be omitted, replaced or modified in various forms without departing from the scope and spirit of the appended claims.

For example, although the case where the drying liquid is IPA has been described in the above embodiments, the drying liquid is not limited to IPA.

In addition, as described in the above embodiments and modifications, the configuration and arrangement of the temperature adjustment part functioning as the substrate heating part or the substrate cooling part may be changed as appropriate. For example, although the case where the first temperature adjusters 61 and 71 that cool down the entire surface of the wafer W are provided at the side of the back surface (the side of the holding part 31) of the wafer W has been described in the above embodiments, they may be provided at the side of the front surface of the wafer W.

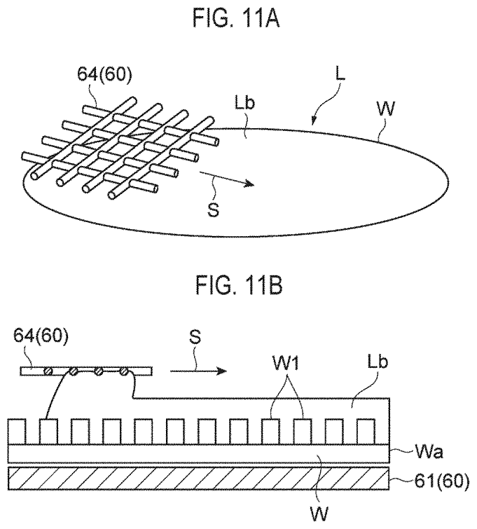

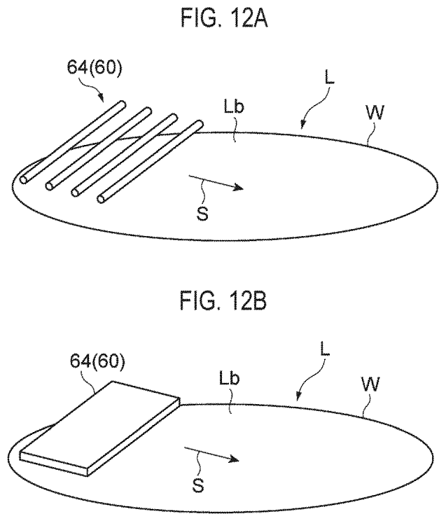

When viewed from above, not only the temperature difference may be generated between different areas (the drying target area A1 and the unprocessed area A2) on the front surface of the wafer W, but also a temperature difference may be generated in the IPA liquid film L in the vertical direction (a height direction of the IPA liquid film L). For example, as shown in FIGS. 11A and 11B, and FIGS. 12A and 12B, the temperature adjustment part 60 may include a first temperature adjuster 61 disposed at the side of the back surface of the wafer W and a fourth temperature adjuster 64 (a low temperature member) disposed at the side of the front surface of the wafer W. The fourth temperature adjuster 64 is configured to move along the front surface of the wafer W above the wafer W. The fourth temperature adjuster 64 may be set to have a temperature lower than that of the first temperature adjuster 61 that heats the water W. That is to say, the fourth temperature adjuster 64 may be set to have a temperature lower than that of the wafer W heated by the first temperature adjuster 61. As a result, a temperature difference occurs between an upper portion of the IPA liquid film L that is brought into contact with the fourth temperature adjuster 64 and a lower portion of the IPA liquid film L that is brought into contact with the wafer W. Thus, a surface tension acting on the upper portion becomes relatively large (Marangoni effect). Therefore, the IPA liquid film L is attracted to the fourth temperature adjuster 64. Accordingly, as the controller 18 controls the operation of the fourth temperature adjuster 64 so that the fourth temperature adjuster 64 moves along the front surface of the wafer W (see an arrow S in FIGS. 11A and 11B, and FIGS. 12A and 12B), the IPA liquid film L also moves along the front surface of the wafer W with the movement of the fourth temperature adjuster 64. As a result, by appropriately controlling the movement direction and movement speed of the fourth temperature adjuster 64 by the controller 18, it is possible to discharge the IPA from the front surface of the wafer W at a desired path and speed.

The fourth temperature adjuster 64 may have a mesh shape as shown in FIGS. 11A and 11B. In this case, as shown in FIG. 11B, an IPA is adsorbed in a mesh space by a capillary phenomenon. Therefore, since the IPA liquid film L easily moves with the movement of the fourth temperature adjuster 64, the IPA can be more effectively discharged from the front surface of the wafer W.

The fourth temperature adjuster 64 may be constituted by one or more rod-shaped bodies as shown in FIG. 12A. The rod-shaped body may have a linear shape, a curved shape, or a meandering shape. In the case where the fourth temperature adjuster 64 is constituted by a plurality of rod-shaped bodies, the rod-shaped bodies may be arranged substantially in a mutually parallel spaced-apart relationship, and may move along the direction of the arrangement. Even in the case where the fourth temperature adjuster 64 is constituted by the plurality of rod-shaped bodies, an IPA is adsorbed in a mesh space by a capillary phenomenon. Therefore, since the IPA liquid film L easily moves with the movement of the fourth temperature adjuster 64, the IPA can be more effectively discharged from the front surface of the wafer W.

The fourth temperature adjuster 64 may be constituted by a plate-shaped body as shown in FIG. 12B. The plate-shaped body may have a flat plate shape, or may have the same shape as the wafer W. A lower surface of the plate-shaped body that faces the front surface of the wafer W may have an uneven shape. Even in the case where the lower surface of the plate-shaped body has an uneven shape, an IPA is adsorbed in a mesh space by a capillary phenomenon. Therefore, since the IPA liquid film L easily moves with the movement of the fourth temperature adjuster 64, the IPA can be more effectively discharged from the front surface of the wafer W.

Although not shown, the fourth temperature adjuster 64 may have a shape other than the above-described shapes, such as a ring shape. The fourth temperature adjuster 64 may move linearly above the wafer W. Alternatively, the fourth temperature adjuster 64 may swing above the wafer W by rotating around a predetermined vertical axis.

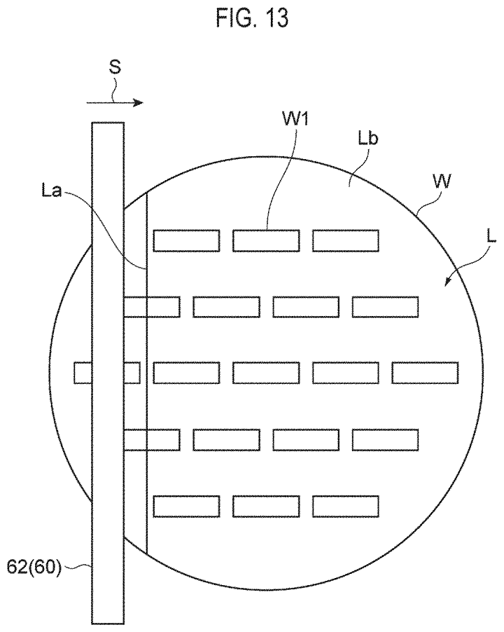

The plurality of patterns W1 formed on the front surface of the wafer W may be regularly arranged along a predetermined direction. For example, as shown in FIG. 13, when all the patterns W1 have substantially a rectangular parallelepiped shape when viewed from above, the patterns W1 may all extend along the predetermined direction (the left-right direction in FIG. 13). In this case, a temperature gradient may be formed on the front surface of the wafer W so that the drying target area A1 moves to the unprocessed area A2 in conformity to the shape of the patterns W1. For example, in the case where the temperature adjustment part 60 includes the first temperature adjuster 61 and the second temperature adjuster 62 of the above-described first embodiment, the second temperature adjuster 62 may move in conformity to the shape of the patterns W1, may move along a lengthwise direction of the pattern W1. Alternatively, the second temperature adjuster 62 may move along a width direction of the pattern W1. When the IPA moves in conformity to the shape of the patterns W1, discharging of the IPA is not easily inhibited by the patterns W1. Therefore, even in the case where the patterns W1 are formed on the front surface of the wafer W, the movement of the IPA becomes smooth, thereby preventing the patterns W1 from being damaged when the IPA is discharged from the front surface of the wafer W.

In order to form a temperature gradient on the front surface of the wafer W so that the drying target area A1 moves toward the unprocessed area A2 in conformity to the patterns W1, the substrate processing apparatus 10 may further include an acquisition means configured to acquire the shape of the patterns W1. The acquisition means may include an imaging part configured to image the front surface of the wafer W, and a processing part configured to process a captured image of the front surface of the wafer W imaged by the imaging part to determine the shape of the patterns W1. In a case where a cutout portion is formed in the wafer W and the directionality of the patterns W1 is determined for the cutout portion in advance, the acquisition means may be configured to acquire a position of the cutout portion. The cutout portion may be, for example, a notch (a U-shaped groove, a V-shaped groove, etc.), or may be a linear portion (so-called orientation flat) extending linearly. For example, the controller 18 may be configured to determine the discharge direction of IPA from the front surface of the wafer W based on the shape of the patterns W1 acquired by the acquisition means. In this case, a temperature gradient may be formed on the front surface of the wafer W so that the IPA liquid film L moves from the drying target area A1 toward the unprocessed area A2 along the determined discharge direction. Therefore, the IPA discharge direction can be automatically set according to the shape of the patterns W1.

The substrate processing apparatus 10 may further include a surrounding member configured to surround the wafer W by being positioned in proximity to the periphery of the wafer W. An upper surface of the surrounding member may be located at substantially the same height as the front surface of the wafer W, and may extend along the horizontal direction. The upper surface of the surrounding member may be an inclined surface that inclines downward from an inner peripheral edge located at substantially the same height as the front surface of the wafer W toward an outer peripheral edge thereof. The surrounding member may be set to have a temperature lower than that of the wafer W. The substrate processing apparatus 10 may further include a gas supply part configured to inject a gas set to have a temperature lower than that of the wafer W toward the upper surface of the surrounding member.

Even in any of the above cases, in order to promote the movement of the IPA, the wafer W may be inclined along the movement direction of the IPA (the movement direction of the drying target area A1).

### EXAMPLES

### Example 1

In an illustrative embodiment, a substrate processing apparatus may include a substrate holding part configured to hold a substrate, a drying liquid supply part configured to supply a drying liquid toward a front surface of the substrate held by the substrate holding part, a temperature adjustment part configured to change a temperature of the front surface of the substrate, and a controller configured to control the temperature adjustment part. The controller may control the temperature adjustment part to generate a temperature difference in a liquid film of the drying liquid supplied onto the front surface of the substrate. As described above, when a temperature difference occurs in the liquid film of the drying liquid supplied to the front surface of the substrate, a Marangoni convection occurs in an area where the temperature difference in the liquid film occurs, and the drying liquid moves due to the Marangoni convection. Accordingly, the drying liquid can be discharged from the front surface of the substrate by the movement of the drying liquid. With this configuration, as compared with a case where the drying liquid is discharged from the front surface of the substrate by virtue of an external force, it is possible to reduce the influence on patterns on the front surface of the substrate and to prevent the patterns from being damaged when removing the drying liquid from the front surface of the substrate.

### Example 2

In the apparatus of Example 1, the front surface of the substrate may include a drying target area to be subjected to a drying process, and an unprocessed area not to be subjected to the drying process, and the controller may control the temperature adjustment part to generate a temperature difference between the drying target area and the unprocessed area. In this case, the Marangoni convection occurs in an area between the drying target area and the unprocessed area in the liquid film, and the drying liquid moves due to the Marangoni convection. Therefore, the drying liquid can be discharged from the front surface of the substrate by the movement of the drying liquid.

### Example 3

In the apparatus of Example 2, the temperature adjustment part may include a substrate cooling part configured to cool down the substrate, and a substrate heating part configured to heat the substrate. The substrate heating part may change a heating position in the front surface of the substrate by moving a line-shaped heat source along the front surface of the substrate. By using the substrate heating part that moves the line-shaped heat source along the front surface of the substrate, an area where the Marangoni convection is generated can be finely controlled, thus appropriately removing the drying liquid.

### Example 4

In the apparatus of Example 2 or Example 3, the temperature adjustment part may include a substrate cooling part configured to cool down the substrate, and a substrate heating part configured to heal the substrate. The substrate cooling part may cool down the entire surface of the substrate. In the case where the entire surface of the substrate is cooled down by the substrate cooling part, it is possible to form a temperature gradient in an area where the Marangoni convection is generated, by using the substrate heating part while maintaining the entire substrate at a predetermined temperature, thus appropriately removing the drying liquid.

### Example 5

In the apparatus of Example 3, the substrate cooling part may cool down the substrate by traveling a line-shaped cooling source in a parallel relationship with the substrate heating part along the front surface of the substrate. In this case, by combining the substrate cooling part and the substrate heating part, it is possible to form a temperature gradient in a desired area where the Marangoni convection is generated, thus appropriately removing the drying liquid.

### Example 6

In the apparatus of any one of Examples 2 to 5, the controller may control the temperature adjustment part to form the temperature gradient on the front surface of the substrate so that the liquid film moves from the drying target area toward the unprocessed area. By forming the temperature gradient on the front surface of the substrate so that the liquid film moves from the drying target area toward other area, the movement of the drying liquid due to the temperature gradient formed on the front surface of the substrate becomes smooth, which makes it possible to prevent pattern damage at the time of removing the drying liquid.

### Example 7

In the apparatus of Example 6, a pattern having a predetermined shape may be formed on the front surface of the substrate. The controller may control the temperature adjustment part to form the temperature gradient on the front surface of the substrate so that the liquid film moves from the drying target area toward the unprocessed area in conformity to the pattern. In this case, since the drying liquid moves in conformity to the pattern, the discharging of the drying liquid is not easily inhibited by the pattern. Therefore, even if the pattern is formed on the front surface of the substrate, the movement of the drying liquid becomes smooth, which makes it possible to prevent pattern damage at the time of discharging the drying liquid from the front surface of the substrate.

### Example 8

In the apparatus of Example 2, the temperature adjustment part may include a substrate heating part configured to heat a portion of the front surface of the substrate. The controller may increase a heating amount of the substrate heating part with a lapse of a period of time during which the temperature gradient is formed on the front surface of the substrate. By using the substrate heating part, it is possible to form the temperature gradient in a desired area where the Marangoni convection is generated, thus appropriately removing the drying liquid.

### Example 9

In the apparatus of Example 1, the temperature adjustment part may include a low temperature member set to have a temperature lower than that of the substrate. The controller may control the temperature adjustment part so that the low temperature member moves along the front surface of the substrate over the substrate in a state where the low temperature member is brought into contact with the liquid film. In this case, a portion of the liquid film that is brought into contact with the low temperature member has a lower temperature than the portion of the liquid film that is brought into contact with the substrate, so that a relatively large surface tension (Marangoni effect) occurs. Therefore, the liquid film is attracted to the low temperature member. Accordingly, by moving the low temperature member along the front surface of the substrate, the liquid film also moves along the front surface of the substrate with the movement of the low temperature member. As a result, it is possible to discharge the drying liquid from the front surface of the substrate at a desired path and speed while appropriately controlling the movement direction and movement speed of the low temperature member.

### Example 10

In the apparatus of any one of Examples 1 to 9, the substrate holding part may be configured to incline the substrate. By providing the substrate in an incline manner, it is possible to prompt the movement of the drying liquid using the Marangoni convection, thus increasing the removal speed of the drying liquid.

### Example 11

In the apparatus of Example 2, the temperature adjustment part may include a substrate cooling part configured to cool down the entire surface of the substrate, and a substrate heating part configured to heat an area including a center of the substrate. By heating the area including the center of the substrate by the substrate heating part while cooling down the entire surface of the substrate by the substrate cooling part, it is possible to form a temperature gradient extending in an annular shape from the area including the center of the substrate. Therefore, the drying liquid can be moved toward the outer periphery of the substrate using the Marangoni convection, and the drying liquid can be appropriately removed.

### Example 12

In the substrate processing apparatus of Example 2, the temperature adjustment part may include a substrate heating part configured to form the temperature gradient in which the heating temperature is highest in an area including a center of the substrate and is decreased from the area including the center of the substrate toward an outer periphery of the substrate. By using the substrate heating part, it is possible to form a temperature gradient that extends in an annular shape from the area including the center of the substrate. Therefore, the drying liquid can be moved toward the outer periphery of the substrate using the Marangoni convection, and the drying liquid can be appropriately removed.

### Example 13

In another illustrative embodiment, a method of processing a substrate may include supplying a drying liquid to a front surface of a substrate held by a substrate holding part, and discharging the drying liquid from the front surface of the substrate by generating a temperature difference in a liquid film of the drying liquid. In this case, the same operation and effects as Example 1 may be achieved.

### Example 14

In the method of Example 13, the front surface of the substrate on which the liquid film is formed may include a drying target area to be subjected to a drying process, and an unprocessed area not to be subjected to the drying process. The discharging the drying liquid may include forming the temperature gradient on the front surface of the substrate so that the liquid film moves from the drying target area toward the unprocessed area. In this case, it is possible to finely controlling the movement of the liquid film of the drying liquid using the temperature gradient, thus appropriately removing the drying liquid.

### Example 15

In the method of Example 14, a pattern having a predetermined shape may be formed on the front surface of the substrate. The discharging the drying liquid may include forming the temperature gradient on the front surface of the substrate so that the liquid film moves from the drying target area toward the unprocessed area in conformity to the pattern. In this case, the same operation and effects as Example 7 may be achieved,

### Example 16

The method of Example 15 may further include determining a direction of discharging of the drying liquid by acquiring a shape of the pattern. The discharging the drying liquid may include forming the temperature gradient on the front surface of the substrate so that the liquid film moves from the drying target area toward the unprocessed area along the determined discharging direction. In this case, it becomes possible to automatically set the discharging direction of the drying liquid in conformity to the shape of the pattern.

### Example 17

In the method of any one of Examples 14 to 16, the discharging the drying liquid may include moving the liquid film of the drying liquid by moving a heating position from a first peripheral portion of the substrate to a second peripheral portion of the substrate. In this case, it is possible to discharge the drying liquid by moving the heating position from the first peripheral portion of the substrate to the second peripheral portion. Accordingly, the drying liquid can be appropriately removed.

### Example 18

In another illustrative embodiment, a non-transitory computer-readable storage medium stores a program for causing the apparatus to execute the method of any one of Examples 13 to 17. In this case, the same operation and effects as the above-described substrate processing method may be achieved. In the present disclosure, the computer-readable storage medium includes a non-transitory tangible medium (non-transitory computer recording medium) (for example, various main storage devices or auxiliary storage devices) and a propagation signal (transitory computer recording medium) (for example, a data signal that can be provided via a network).

According to the present disclosure in some embodiments, it is possible to prevent pattern damage at the time of removing a drying liquid from a front surface of a substrate.

What is claimed is:

1. A substrate processing apparatus comprising:
a substrate holding part configured to hold a substrate;
a drying liquid supply part configured to supply a drying liquid toward a front surface of the substrate held by the substrate holding part;
a temperature adjustment part configured to change a temperature of the front surface of the substrate; and
a controller configured to control the temperature adjustment part,
wherein the controller controls the temperature adjustment part to generate a temperature difference in a liquid film of the drying liquid supplied onto the front surface of the substrate.

2. The substrate processing apparatus of claim 1, wherein the front surface of the substrate includes a drying target area to be subjected to a drying process, and an unprocessed area not to be subjected to the drying process, and
wherein the controller controls the temperature adjustment part to generate a temperature difference between the drying target area and the unprocessed area.

3. The substrate processing apparatus of claim 2, wherein the temperature adjustment part includes a substrate cooling part configured to cool down the substrate, and a substrate heating part configured to heat the substrate, and
wherein the substrate heating part changes a heating position in the front surface of the substrate by moving a line-shaped heat source along the front surface of the substrate.

4. The substrate processing apparatus of claim 3, wherein the substrate cooling part cools down the entire surface of the substrate.

5. The substrate processing apparatus of claim 3, wherein the substrate cooling part cools down the substrate by traveling a line-shaped cooling source in a parallel relationship with the substrate heating part along the front surface of the substrate.

6. The substrate processing apparatus of claim 2, wherein the temperature adjustment part includes a substrate cooling part configured to cool down the substrate, and a substrate heating part configured to heat the substrate, and
wherein the substrate cooling part cools down an entire surface of the substrate.

7. The substrate processing apparatus of claim 2, wherein the controller controls the temperature adjustment part to form the temperature gradient on the front surface of the substrate so that the liquid film moves from the drying target area toward the unprocessed area.

8. The substrate processing apparatus of claim 7, wherein a pattern having a predetermined shape is formed on the front surface of the substrate, and
wherein the controller controls the temperature adjustment part to form the temperature gradient on the front surface of the substrate so that the liquid film moves from the drying target area toward the unprocessed area in conformity to the pattern.

9. The substrate processing apparatus of claim 2, wherein the temperature adjustment part includes a substrate heating part configured to heat a portion of the front surface of the substrate, and
wherein the controller increases a heating amount of the substrate heating part with an lapse of a period of time during which the temperature gradient is formed on the front surface of the substrate.

10. The substrate processing apparatus of claim 2, wherein the substrate holding part is configured to incline the substrate.

11. The substrate processing apparatus of claim 2, wherein the temperature adjustment part includes a substrate cooling part configured to cool down an entire surface of the substrate, and a substrate heating part configured to heat an area including a center of the substrate.

12. The substrate processing apparatus of claim 2, wherein the temperature adjustment part includes a substrate heating part configured to form the temperature gradient in which the heating temperature is highest in an area including a center of the substrate and is decreased from the area including the center of the substrate toward an outer periphery of the substrate.

13. The substrate processing apparatus of claim 1, wherein the temperature adjustment part includes a low temperature member set to have a temperature lower than that of the substrate, and
wherein the controller controls the temperature adjustment part so that the low temperature member moves along the front surface of the substrate over the substrate in a state where the low temperature member is brought into contact with the liquid film.

14. The substrate processing apparatus of claim 1, wherein the substrate holding part is configured to incline the substrate.

15. A method of processing a substrate, comprising:
supplying a drying liquid to a front surface of a substrate held by a substrate holding part; and
discharging the drying liquid from the front surface of the substrate by generating a temperature difference in a liquid film of the drying liquid.

16. The method of claim 15, wherein the front surface of the substrate on which the liquid film is formed includes a drying target area to be subjected to a drying process, and an unprocessed area not to be subjected to the drying process, and
wherein the discharging the drying liquid includes forming the temperature gradient on the front surface of the substrate so that the liquid film moves from the drying target area toward the unprocessed area.

17. The method of claim 16, wherein a pattern having a predetermined shape is formed on the front surface of the substrate, and
wherein the discharging the drying liquid includes forming the temperature gradient on the front surface of the substrate so that the liquid film moves from the drying target area toward the unprocessed area in conformity to the pattern.

18. The method of claim 17, further comprising: determining a direction of discharging of the drying liquid by acquiring a shape of the pattern,
wherein the discharging the drying liquid includes forming the temperature gradient on the front surface of the substrate so that the liquid film moves from the drying target area toward the unprocessed area along the determined discharging direction.

19. The method of claim 16, wherein the discharging the drying liquid includes moving the liquid film of the drying liquid by moving a heating position from a first peripheral portion of the substrate to a second peripheral portion of the substrate.

20. A non-transitory computer-readable storage medium storing a program that causes an apparatus to execute the method of claim 15.
